(19) United States
(12) Patent Application Publication
(10) Pub. No.: US 2026/0040639 A1
(43) Pub. Date: Feb. 5, 2026

(54) SEMICONDUCTOR DEVICE HAVING FLEXIBLE ASSEMBLED ABUTTING REGIONS

(71) Applicant: TAIWAN SEMICONDUCTOR MANUFACTURING COMPANY LTD., HSINCHU (TW)

(72) Inventors: WAN-JIUN LIAO, TAICHUNG CITY (TW); YOU-CHENG XIAO, TAICHUNG CITY (TW); CHIA-EN HUANG, HSINCHU COUNTY (TW); JUNG-HSUAN CHEN, HSINCHU CITY (TW); TING-WEI CHIANG, NEW TAIPEI CITY (TW)

(21) Appl. No.: 18/792,607

(22) Filed: Aug. 2, 2024

(51) Int. Cl. H01L 29/06; H01L 29/24

(52) U.S. Cl. CPC H10D 62/126; H10D 62/80

(57) ABSTRACT

A semiconductor device comprises a first functional block. The first functional block includes a first region having a first oxide diffusion region and a second oxide diffusion region. A first assembled abutting region is adjacent to the first region and comprises a first dummy oxide diffusion region and a second dummy oxide diffusion region. The first oxide diffusion region is contact with the first dummy oxide diffusion region. The second oxide diffusion region is contact with the second dummy oxide diffusion region. An end of the first dummy oxide diffusion region is aligned with a boundary of the first functional block from a top view. An end of the second dummy oxide diffusion region is aligned with the boundary of the first functional block from a top view.

### TECHNICAL FIELD

The present disclosure relates in general to semiconductor devices. Specifically, the present disclosure relates to a semiconductor device having flexible assembled abutting regions.

### BACKGROUND

One problem faced in nanotechnology development is that, while suitable range of widths can be selected for oxide diffusion regions, area loss or waste occurs at the interface between wider and narrower oxide diffusion regions. Therefore, manufacturers are required to provide an oxide diffusion transition region to ensure transistor function availability. Reduction of cell area of the semiconductor structure and optimization of process is thus called for.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A is a top view of a semiconductor device in accordance with some embodiments of the present disclosure.

FIG. 1B is a top view of a semiconductor device in accordance with some embodiments of the present disclosure.

FIG. 1C is a top view of a semiconductor device in accordance with some embodiments of the present disclosure.

FIG. 2 is a top view of a semiconductor device in accordance with some embodiments of the present disclosure.

FIG. 3A is a top view of a semiconductor device in accordance with some embodiments of the present disclosure.

FIG. 3B is a top view of a semiconductor device in accordance with some embodiments of the present disclosure.

FIG. 4A is a top view of a semiconductor device in accordance with some embodiments of the present disclosure.

FIG. 4B is a top view of a semiconductor device in accordance with some embodiments of the present disclosure.

FIG. 5 is a top view of a semiconductor device in accordance with some embodiments of the present disclosure.

FIG. 6 is a top view of a semiconductor device in accordance with some embodiments of the present disclosure.

FIG. 7 is a top view of a semiconductor device in accordance with some embodiments of the present disclosure.

FIG. 8 is a top view of a semiconductor device in accordance with some embodiments of the present disclosure.

FIG. 9A is a top view of a semiconductor device in accordance with some embodiments of the present disclosure.

FIG. 9B shows two cross-sections of the semiconductor device along lines A-A and A′-A′ of FIG. 9A in accordance with some embodiments of the present disclosure.

FIG. 10A is a top view of a semiconductor device in accordance with some embodiments of the present disclosure.

FIG. 10B shows two cross-sections of the semiconductor device along lines B-B and B′-B′ of FIG. 10A in accordance with some embodiments of the present disclosure.

FIG. 11 is a flowchart of an embodiment of a method of manufacturing a semiconductor device in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° (degree) or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A problem faced by existing process is the difficulty in the nanotechnology. The designers can choose a suitable range width for the oxide diffusion region. To reduce the cell area of the semiconductor structure and optimize the process is called for.

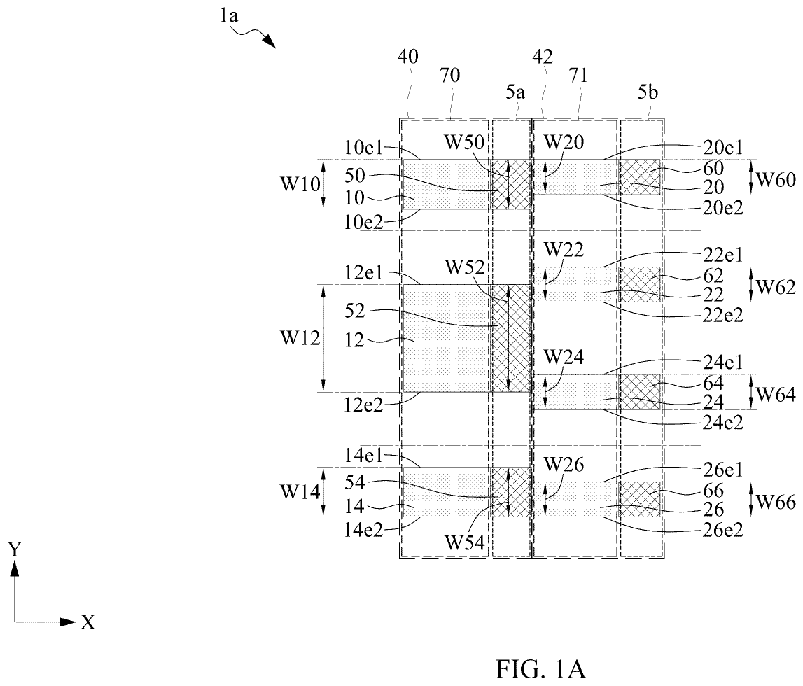

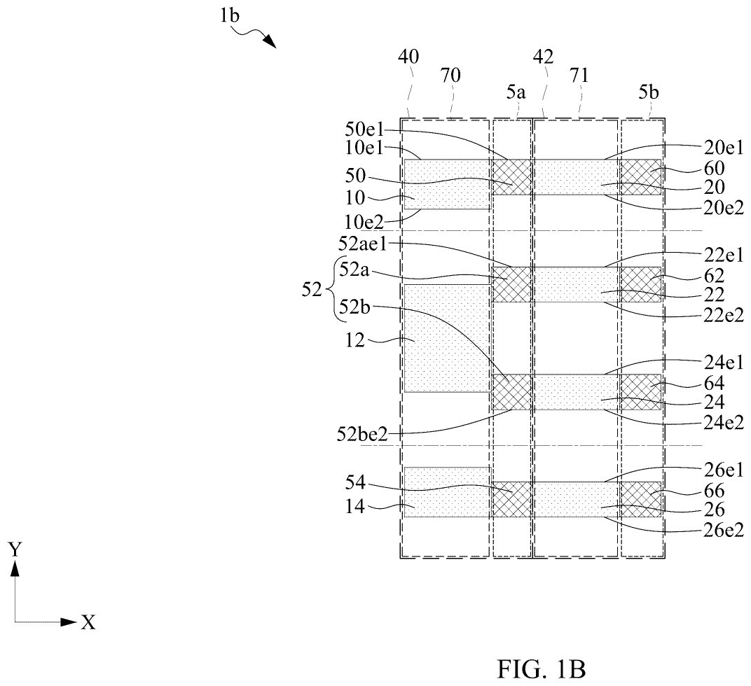

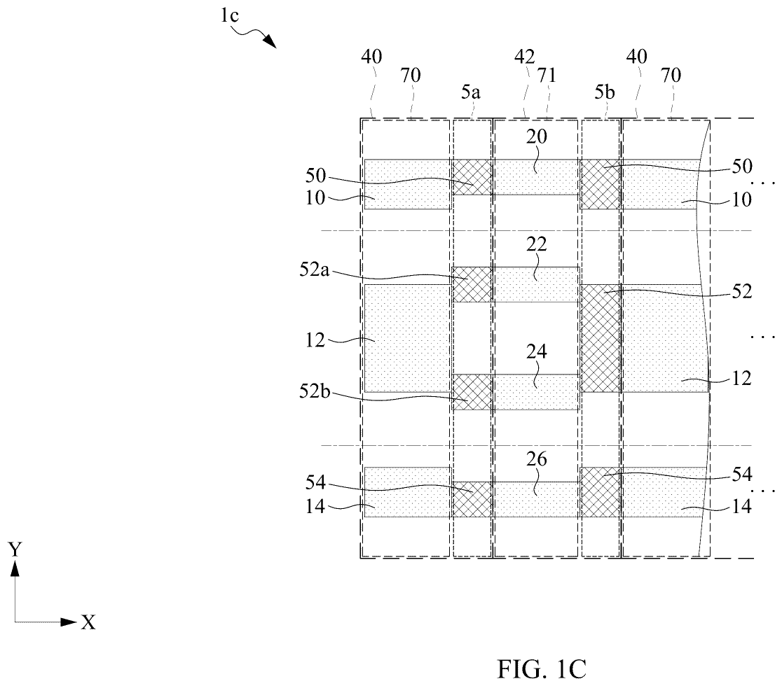

FIG. 1A is a top view of a semiconductor device 1a in accordance with some embodiments of the present disclosure. The semiconductor device 1a includes a functional block 40 and a functional block 42. In some embodiments, functional block 40 is adjacent to functional block 42. The left edge of functional block 40 can be adjacent to another functional block (not shown) and the right edge of functional block 42 can be adjacent to another functional block (not shown).

In some embodiments, functional block 40 includes a region 70, which is a double height cell region, and functional block 42 includes a region 71 which is formed of two single height cell regions. In some embodiments, the region 70 may be formed of two single height cell regions and region 71 may be a double height cell region. In some embodiments, regions 70 and 71 may be a combination of at least one single height cell region and at least one double height cell region, or other suitable combinations. In some embodiments, each of the functional blocks 40 and 42 may be the smallest functional unit in a semiconductor device.

In some embodiments, functional block 40 includes a region 70 and an assembled abutting region 5a. Functional block 42 includes a region 71 and an assembled abutting region 5b. The region 70 has an oxide diffusion (OD) region 10, an oxide diffusion region 12, and oxide diffusion region 14. Assembled abutting region 5a is adjacent to the region 70. Region 71 has oxide diffusion regions 20, 22, 24, and 26. Assembled abutting region 5b is adjacent to region 71. In some embodiments, the term “oxide diffusion region” discussed in the present disclosure may also be referred to as an active region.

Assembled abutting region 5a comprises a dummy oxide diffusion region 50, a dummy oxide diffusion region 52, and a dummy oxide diffusion region 54. Assembled abutting region 5b comprises dummy oxide diffusion regions 60, 62, 64, and 66.

In some embodiments, oxide diffusion region 10 contacts dummy oxide diffusion region 50, and oxide diffusion region 12 contacts the dummy oxide diffusion region 52. In some embodiments, an end of dummy oxide diffusion region 50 (e.g., the end in the right hand) is aligned with a boundary of functional block 40 from a top view. An end of dummy oxide diffusion region 52 (e.g., the end in the right hand) is aligned with the boundary of functional block 40 from a top view. In some embodiments, oxide diffusion region 20 is contact with dummy oxide diffusion region 60, and oxide diffusion region 22 is contact with dummy oxide diffusion region 62. Oxide diffusion region 24 is contact with dummy oxide diffusion region 64 and oxide diffusion region 26 is contact with dummy oxide diffusion region 66.

In some embodiments, an end of dummy oxide diffusion region 60 (e.g., the end in the right hand) is aligned with a boundary of functional block 42 from a top view. The ends of dummy oxide diffusion regions 62, 64, and 66 are respectively aligned with the boundary of functional block 42 from a top view. In some embodiments, oxide diffusion region 20 contacts dummy oxide diffusion region 60, and oxide diffusion region 20 contacts dummy oxide diffusion region 50. In some embodiments, the width W20 of the oxide diffusion region 20 is smaller than the width W50 of the dummy oxide diffusion region 50. The width W20 of the oxide diffusion region 20 is smaller than the width W10 of the oxide diffusion region 10.

In some embodiments, oxide diffusion regions 10, 12, and 14 include a plurality of active regions or doped regions having functions defined therein, oxide diffusion regions 20, 22, 24, and 26 include a plurality of active regions or doped regions having functions defined therein. The oxide diffusion regions 10, 12, and 14 may include operable transistors formed therein. The oxide diffusion regions 20, 22, 24, and 26 may include operable transistors formed therein. In some embodiments, the active/doped regions include a semiconductor material such as silicon. In some embodiments, a portion of the active/doped regions is surrounded by a gate dielectric layer (not shown). The gate dielectric layer may be conformally deposited over the semiconductor material of the active/doped regions. In some embodiments, the active/doped regions include a gate dielectric layer (not shown) contacting a metal gate. The metal gate is electrically connected to an external conductive contact. The metal gate includes conductive material, such as aluminum (Al), copper (Cu), tungsten (W), titanium (Ti), tantalum (Ta), or other applicable materials. In some embodiments, the metal gate includes a work function layer. The work function layer is metal, and the metal includes N-work-function metal or P-work-function metal. The N-work-function metal includes tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal includes titanium nitride (TiN), tungsten nitride (WN), tantalum nitride (TaN), ruthenium (Ru) or a combination thereof. Other suitable materials are within the contemplated scope of the disclosure.

In some embodiments, the gate dielectric layer includes silicon oxide (SiOₓ), silicon nitride (SiₓN_{y}), silicon oxynitride (SiON), or a combination thereof. In some embodiments, the gate dielectric layer includes dielectric material(s), such as high-k dielectric material. The high-k dielectric material has a dielectric constant (k value) greater than 4. The high-k material includes hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material.

In some embodiments, dummy oxide diffusion regions 50, 52, and 54 are similar to oxide diffusion regions 10. However, dummy oxide diffusion regions 50, 52, and 54 include a plurality of doped regions without defining any function thereof. In some embodiments, dummy oxide diffusion regions 50, 52, and 54 do not include operable transistors. In some embodiments, metal gates of dummy oxide diffusion regions 50, 52, and 54 are not provided with any voltage. The metal gates of dummy oxide diffusion regions 50, 52, and 54 are dummy gates. Dummy oxide diffusion regions 50, 52, and 54 are not configured for NMOS or PMOS technology. In some embodiments, dummy oxide diffusion regions 50, 52, and 54 are positioned to provide isolation.

In some embodiments, functional block 42 includes a region 71 and an assembled abutting region 5b. Region 71 has an oxide diffusion region 20 contacting dummy oxide diffusion region 50 and an oxide diffusion region 22 contacting dummy oxide diffusion region 52 from a top view. In some embodiments, an assembled abutting region 5b is adjacent to region 71. Assembled abutting region 5b comprises a dummy oxide diffusion region 60 contacting oxide diffusion region 20 and a dummy oxide diffusion region 62 contacting oxide diffusion region 22. In some embodiments, an end of dummy oxide diffusion region 60 aligns with a boundary of functional block 42 and an end of dummy oxide diffusion region 62 is aligned with the boundary of functional block 42 from a top view.

In some embodiments, a width W60 of the dummy oxide diffusion region 60 is smaller than a width W10 of the oxide diffusion region 10 and a width W62 of the dummy oxide diffusion region 62 is smaller than a width W12 of the oxide diffusion region 12. Width W50 of dummy oxide diffusion region 50 is different from a width W60 of dummy oxide diffusion region 60 from a top view. Width W52 of dummy oxide diffusion region 52 is different from the width W22 of oxide diffusion region 22. A width W20 of the oxide diffusion region 20 is the same as a width W60 of dummy oxide diffusion region 60. A width W22 of oxide diffusion region 22 is the same as a width W62 of the dummy oxide diffusion region 62. A width W12 of oxide diffusion region 12 is the same as a width W52 of the dummy oxide diffusion region 52.

Oxide diffusion region 12 has an edge 12e1 and an edge 12e2 extending along an X-axis orthogonal to the end of dummy oxide diffusion region 52. The oxide diffusion region 22 has an edge 22e1 and an edge 22e2 extending along an X-axis orthogonal to the boundary of functional block 42 from a top view. Edges 12e1 and 12e2 are orthogonal to the boundary of functional block 40 from a top view. Oxide diffusion region 22 has an edge 22e1 adjacent to the edge 12e1 and extending along an X-axis. The edge 22e1 is not aligned with the edge 12e1 from a top view. The edge 22e2 is not aligned with the edge 12e1 from a top view. The oxide diffusion region 20 and the dummy oxide diffusion region 50 collectively form a stepped shape in the conjunction therebetween.

Oxide diffusion region 22 has an edge 22e1 adjacent to the edge 12e1 and extending along an X-axis. The edge 12e1 is not aligned with the edge 22e1 from a top view. Oxide diffusion region 22 has an edge 22e2 opposite to the edge 22e1. An end of the edge 22e2 is in contact with an end of dummy oxide diffusion region 52.

Referring to FIG. 1A, a lower portion of an end of oxide diffusion region 22 contacts dummy oxide diffusion region 52 and an upper portion of an end of oxide diffusion region 24 contacts dummy oxide diffusion region 52 from a top view. The oxide diffusion region 22 and the dummy oxide diffusion region 52 collectively form a stepped shape in the conjunction therebetween. The oxide diffusion region 24 and the dummy oxide diffusion region 52 collectively form a stepped shape in the conjunction therebetween.

The area of the semiconductor device 1a may be reduced by aligning one end of assembled abutting region 5a with the boundary of functional block 40 from a top view and aligning one end of dummy oxide diffusion region 50 with the boundary of functional block 40 from a top view. Since the end of assembled abutting region 5a is aligned with the boundary of functional block 40 along an X-axis from a top view, there is no additional area in assembled abutting region 5a disposed between functional block 40 and dummy oxide diffusion region 50 along an X-axis. In some embodiments, the area of the semiconductor device 1a may be reduced by aligning one end of oxide diffusion region 10 with the boundary of functional block 40 from a top view without affecting the functions of semiconductor structures 1a. In some embodiments, oxide diffusion regions 10 and 14 are configured for NMOS technology (the work function is a N-work-function) and oxide diffusion region 12 is configured for PMOS technology (the work function is a P-work-function). In some embodiments, oxide diffusion regions 20 and 26 are configured for NMOS technology (the work function is a N-work-function) and oxide diffusion regions 22 and 24 are configured for PMOS technology (the work function is a P-work-function). The connection between the two functional blocks 40 and 42 can be designed according to special region arrangement of assembled abutting regions 5a and 5b. In some embodiments, oxide diffusion region 12 is configured for NMOS technology, oxide diffusion regions 22 and 24 are correspondingly configured for NMOS technology and oxide diffusion regions 10, 14, 20, and 26 are configured for PMOS technology.

FIG. 1B is a top view of a semiconductor device 1b in accordance with some embodiments of the present disclosure. The semiconductor device 1b includes a functional block 40 and a functional block 42. In some embodiments, functional block 40 includes a region 70 which is a double height cell region and functional block 42 includes a region 71 which is formed of two single height cell regions. In some embodiments, region 70 may be formed of two single height cell regions and region 71 may be a double height cell region. In some embodiments, regions 70 and 71 may be formed of a combination of at least one single height cell region and at least one double height cell region or other suitable combinations. In some embodiments, each of functional blocks 40 and 42 may be the smallest functional unit in a semiconductor device.

In some embodiments, functional block 40 includes a region 70 and an assembled abutting region 5a. Functional block 42 includes a region 71 and an assembled abutting region 5b. Region 70 has oxide diffusion regions 10, 12, and 14. Assembled abutting region 5a is adjacent to region 70 and region 71. Region 71 has oxide diffusion regions 20, 22, 24, and 26. Assembled abutting region 5b has dummy oxide diffusion regions 60, 62, 64, and 66.

In some embodiments, oxide diffusion region 10 contacts dummy oxide diffusion region 50 and oxide diffusion region 14 contacts dummy oxide diffusion region 54. In some embodiments, an end of dummy oxide diffusion region 50 is aligned with a boundary of functional block 40 from a top view. An end of dummy oxide diffusion region 54 is aligned with a boundary of functional block 40 from a top view.

In some embodiments, dummy oxide diffusion region 52 comprises an upper dummy oxide diffusion region 52a and a lower dummy oxide diffusion region 52b separated from upper dummy oxide diffusion region 52a. A lower portion of upper dummy oxide diffusion region 52a contacts oxide diffusion region 12 and an upper portion of lower dummy oxide diffusion region 52b contacts oxide diffusion region 12 from a top view.

In some embodiments, oxide diffusion regions 22 and 24 are disposed in region 71. Upper dummy oxide diffusion region 52a is aligned with oxide diffusion region 22 and lower dummy oxide diffusion region 52b is aligned with oxide diffusion region 24 from a top view. Oxide diffusion region 26 aligns with dummy oxide diffusion region 54 from a top view. Oxide diffusion region 26 aligns with dummy oxide diffusion region 66 from a top view.

In some embodiments, an end of dummy oxide diffusion region 60 aligns with a boundary of functional block 42 from a top view. The ends of dummy oxide diffusion regions 62, 64, and 66 align with the boundary of functional block 42 from a top view. In some embodiments, the ends of oxide diffusion regions 20, 22, 24, and 26 align with the boundary of functional block 42 from a top view.

In some embodiments, oxide diffusion region 20 contacts dummy oxide diffusion regions 50 and 60. In some embodiments, the width W20 of the oxide diffusion region 20 is substantially equal to the width W50 of the dummy oxide diffusion region 50. The width W20 of the oxide diffusion region 20 is smaller than the width W10 of the oxide diffusion region 10.

In some embodiments, dummy oxide diffusion regions 50, 52, 54, 60, 62, 64, and 66 include a plurality of doped regions without defining any function therein. In some embodiments, dummy oxide diffusion regions 50, 52, 54, 60, 62, 64, and 66 do not include operable transistors. In some embodiments, metal gates of dummy oxide diffusion region 50, 52, 54, 60, 62, 64, and 66 are not connected to the external power supply. The metal gates of dummy oxide diffusion regions 50, 52, 54, 60, 62, 64, and 66 are dummy gates. Dummy oxide diffusion regions 50, 52, 54, 60, 62, 64, and 66 are not configured for NMOS or PMOS technology. In some embodiments, dummy oxide diffusion regions 50, 52, 54, 60, 62, 64, and 66 are positioned to provide isolation. In some embodiments, dummy oxide diffusion regions 50, 52, 54, 60, 62, 64, and 66 are positioned for interconnection only.

Oxide diffusion region 12 has an edge 12e1 and an edge 12e2 extending along an X-axis orthogonal to the ends of dummy oxide diffusion regions 50, 52, and 54. Edges 12e1 and 12e2 are orthogonal to the boundary of functional block 40 from a top view. Oxide diffusion region 20 has an edge 20e1 adjacent to edge 10e1 and extending along an X-axis. Edge 20e1 is not aligned with edge 10e1 from a top view. An edge 52ae1 of the upper dummy oxide diffusion region 52a is aligned with the edge 22e1 of the oxide diffusion region 20 from a top view, and an edge 52be2 of the lower dummy oxide diffusion region 52b is aligned with an edge 24e2 of the oxide diffusion region 24 from a top view. A width W54 of the dummy oxide diffusion region 54 is the same as a width W26 of the oxide diffusion region 26. A width W54 of the dummy oxide diffusion region 54 is respectively the same as a width W64 of the dummy oxide diffusion region 64. A width W54 of the dummy oxide diffusion region 54 is respectively the same as a width W62 of the dummy oxide diffusion region 62. A width W54 of the dummy oxide diffusion region 54 is respectively the same as a width W60 of the dummy oxide diffusion region 60.

The oxide diffusion region 10 and the dummy oxide diffusion region 50 collectively form a stepped profile in the conjunction therebetween. The oxide diffusion region 12 and the upper dummy oxide diffusion region 52a collectively form a stepped profile in the conjunction therebetween. The oxide diffusion region 12 and the lower dummy oxide diffusion region 52b collectively form a stepped profile in the conjunction therebetween. The oxide diffusion region 14 and the dummy oxide diffusion region 54 collectively form a stepped profile in the conjunction therebetween.

In some embodiments, an end of dummy oxide diffusion region 50 is aligned with a boundary of functional block 40 from a top view. An end of oxide diffusion region 50 is aligned with a left edge of the boundary of functional block 40 from a top view. An end of oxide diffusion region 20 is aligned with a left edge of the boundary of functional block 42 from a top view.

In some embodiments, oxide diffusion region 20 contacts dummy oxide diffusion regions 60 and 50. Oxide diffusion region 22 contacts dummy oxide diffusion regions 52a and 62. In some embodiments, an end of dummy oxide diffusion region 66 is aligned with a boundary of functional block 42 from a top view. In some embodiments, the ends of dummy oxide diffusion regions 52a and 52b are respectively aligned with the boundary of functional block 40 from a top view. In some embodiments, the ends of oxide diffusion regions 10, 12, and 14 align with a left edge of the boundary of functional block 40 from a top view. In some embodiments, the ends of oxide diffusion regions 20, 22, 24, and 26 align with a left edge of the boundary of functional block 42 from a top view. In some embodiments, oxide diffusion region 26 contacts dummy oxide diffusion regions 54 and 66.

In some embodiments, oxide diffusion regions 10, 12, 14, 20, 22, 24, and 26 include a plurality of active regions or doped regions having functions defined therein. The oxide diffusion regions 10, 12, 14, 20, 22, 24, and 26 may include operable transistors formed therein. In some embodiments, the active/doped regions include a semiconductor material such as silicon. In some embodiments, a portion of the active/doped regions is surrounded by a gate dielectric layer (not shown).

In some embodiments, dummy oxide diffusion regions 50, 52, 54, 60, 62, 64, and 66 include a plurality of doped regions without defining any function therein. In some embodiments, dummy oxide diffusion regions 50, 52, 54, 60, 62, 64, and 66 do not include operable transistors. In some embodiments, metal gates of dummy oxide diffusion region 50, 52, 54, 60, 62, 64, and 65 are not electrically connected to the external power supply.

In some embodiments, oxide diffusion regions 10 and 14 are configured for NMOS technology (the work function is a N-work-function) and oxide diffusion region 12 is configured for PMOS technology (the work function is a P-work-function). In some embodiments, oxide diffusion regions 20 and 26 are configured for NMOS technology (the work function is a N-work-function) and oxide diffusion regions 22 and 24 are configured for PMOS technology (the work function is a P-work-function). In some embodiments, oxide diffusion region 12 is configured for NMOS technology, oxide diffusion regions 22 and 24 are correspondingly configured for NMOS technology and oxide diffusion regions 10, 14, 20, and 26 are configured for PMOS technology.

FIG. 1C is a top view of a semiconductor device 1c in accordance with some embodiments of the present disclosure. The semiconductor device 1c includes two functional blocks 40 and a functional block 42. In some embodiments, functional block 40 includes a region 70 which is a double height cell region and functional block 42 includes a region 71 which is formed of two single height cell regions.

In some embodiments, functional block 40 includes a region 70 and an assembled abutting region 5a. Functional block 42 includes a region 71 and an assembled abutting region 5b. The region 70 has oxide diffusion regions 10, 12, and 14. Assembled abutting region 5a is adjacent to the region 70 and region 71. Region 71 has oxide diffusion regions 20, 22, 24, and 26. Assembled abutting region 5b has dummy oxide diffusion regions 50, 52, and 54.

In some embodiments, oxide diffusion region 10 contacts dummy oxide diffusion region 50 and oxide diffusion region 20 contacts dummy oxide diffusion region 50. In some embodiments, left oxide diffusion region 50 in assembled abutting region 5a is narrower than right oxide diffusion region 50 in assembled abutting region 5b.

In some embodiments, an end of the left dummy oxide diffusion region 50 is aligned with a boundary of left functional block 40 from a top view. An end of dummy oxide diffusion region 50 in assembled abutting region 5b is aligned with a boundary of functional block 42 from a top view.

In some embodiments, dummy oxide diffusion region 52 in left assembled abutting region 5a comprises an upper dummy oxide diffusion region 52a and a lower dummy oxide diffusion region 52b separated from upper dummy oxide diffusion region 52a. A lower portion of upper dummy oxide diffusion region 52a contacts oxide diffusion region 12 and an upper portion of lower dummy oxide diffusion region 52b contacts oxide diffusion region 12 from a top view.

In some embodiments, oxide diffusion regions 22 and 24 are disposed in region 71. The upper dummy oxide diffusion region 52a is aligned with oxide diffusion region 22 and lower dummy oxide diffusion region 52b is aligned with the oxide diffusion region 24 from a top view. A lower portion of oxide diffusion region 22 contacts right oxide diffusion region 52 and an upper portion of oxide diffusion region 24 contacts right oxide diffusion region 52 from a top view.

In some embodiments, an end of right dummy oxide diffusion region 50 aligns with a boundary of functional block 42 from a top view. The ends of right dummy oxide diffusion regions 50, 52, and 54 align with the boundary of functional block 42 from a top view. In some embodiments, the ends of the oxide diffusion regions 20, 22, 24, and 26 in the region 71 are respectively aligned with the boundary of the functional block 42 from the top view.

In some embodiments, oxide diffusion region 20 contacts the left dummy oxide diffusion region 50 and the right dummy oxide diffusion region 50. The width W20 of the oxide diffusion region 20 is smaller than the width W10 of the oxide diffusion region 10.

In some embodiments, dummy oxide diffusion regions 50, 52, and 54 include a plurality of doped regions without defining any function therein. In some embodiments, dummy oxide diffusion regions 50, 52, and 54 do not include operable transistors. The metal gates of dummy oxide diffusion regions 50, 52, and 54 are dummy gates. Dummy oxide diffusion regions 50, 52, and 54 are not configured for NMOS or PMOS technology. In some embodiments, dummy oxide diffusion regions 50, 52, and 54 are positioned to provide isolation. In some embodiments, dummy oxide diffusion regions 50, 52, and 54 are positioned for only interconnection.

In some embodiments, oxide diffusion regions 10 and 14 are configured for NMOS technology (the work function is a N-work-function) and oxide diffusion region 12 is configured for PMOS technology (the work function is a P-work-function). In some embodiments, oxide diffusion regions 20 and 26 are configured for NMOS technology (the work function is a N-work-function) and oxide diffusion regions 22 and 24 are configured for PMOS technology (the work function is a P-work-function).

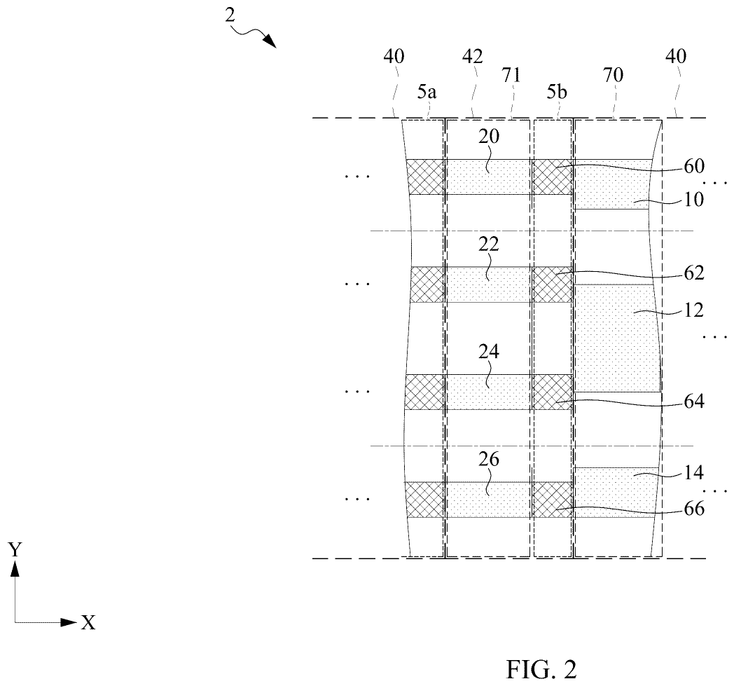

FIG. 2 is a top view of a semiconductor device 2 in accordance with some embodiments of the present disclosure. Semiconductor device 2 includes two functional blocks 40 and a functional block 42. In some embodiments, functional block 40 includes a region 70 which is a double height cell region and functional block 42 includes a region 71 which is formed of two single height cell regions.

In some embodiments, functional block 40 includes a region 70 and an assembled abutting region 5a. Functional block 42 includes a region 71 and an assembled abutting region 5b. Region 70 has oxide diffusion regions 10, 12, and 14. In some embodiments, assembled abutting region 5a is adjacent to region 71. Region 71 has oxide diffusion regions 20, 22, 24, and 26. Assembled abutting region 5b has dummy oxide diffusion regions 60, 62, 64, and 66.

In some embodiments, oxide diffusion region 10 contacts dummy oxide diffusion region 60. Dummy oxide diffusion region 60 contacts oxide diffusion region 20 in region 71. In some embodiments, dummy oxide diffusion region 60 in assembled abutting region 5b is narrower than right oxide diffusion region 10 in the region 70.

In some embodiments, an end of dummy oxide diffusion region 60 aligns with a boundary of the functional block 42 from a top view. An end of oxide diffusion region 20 aligns with a left edge of the boundary of functional block 42 from a top view.

In some embodiments, dummy oxide diffusion region 62 in right assembled abutting region 5b is separated from dummy oxide diffusion region 64 in right assembled abutting region 5b. A lower portion of dummy oxide diffusion region 62 contacts oxide diffusion region 12 and an upper portion of dummy oxide diffusion region 64 contacts oxide diffusion region 12 from a top view.

In some embodiments, dummy oxide diffusion regions 60, 62, 64, and 66 include a plurality of doped regions without defining any function therein. The metal gates of dummy oxide diffusion regions 60, 62, 64, and 66 are dummy gates. Dummy oxide diffusion regions 60, 62, 64, and 66 are not configured for NMOS or PMOS technology.

In some embodiments, oxide diffusion regions 10 and 14 are configured for NMOS technology (the work function is a N-work-function) and oxide diffusion region 12 is configured for PMOS technology (the work function is a P-work-function). In some embodiments, oxide diffusion regions 20 and 26 are configured for NMOS technology (the work function is a N-work-function) and oxide diffusion regions 22 and 24 are configured for PMOS technology (the work function is a P-work-function).

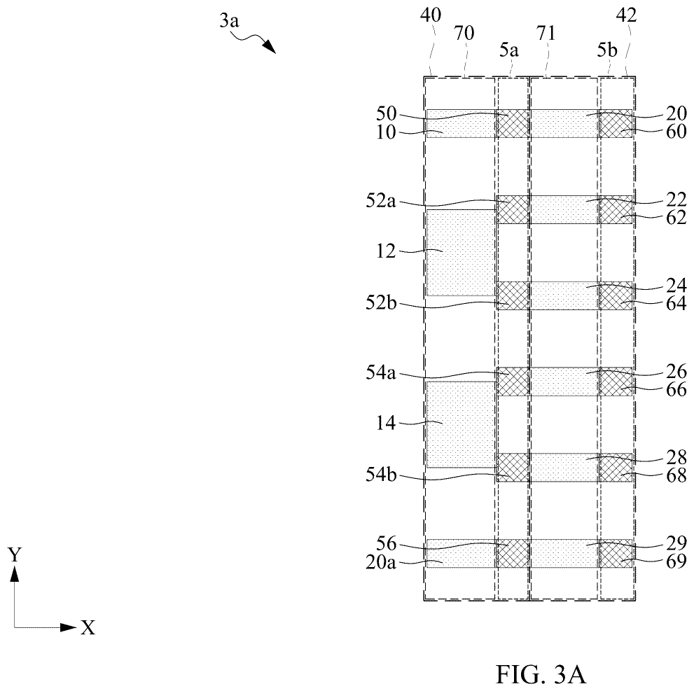

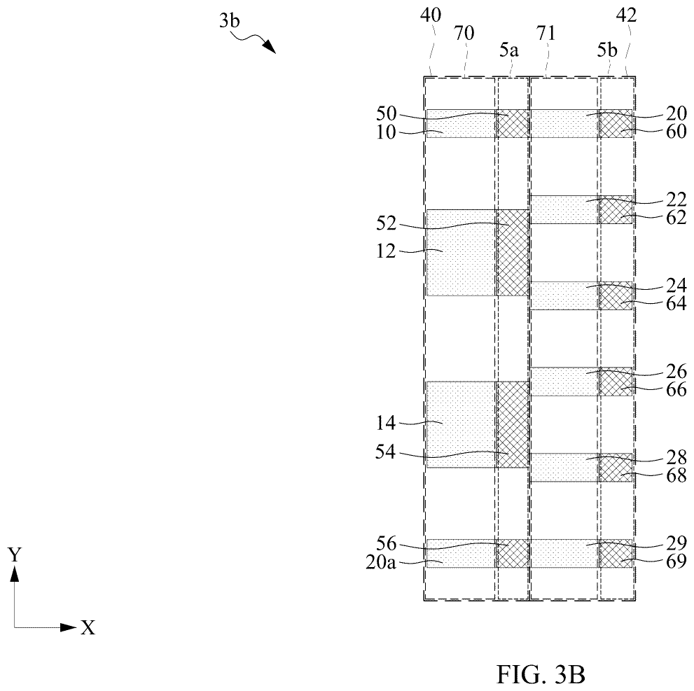

FIG. 3A is a top view of a semiconductor device 3a in accordance with some embodiments of the present disclosure. The semiconductor device 3a includes a functional block 40 and a functional block 42. In some embodiments, functional block 40 includes a region 70 which includes two double height cell regions and functional block 42 includes a region 71 which includes three single height cell regions.

One cell of the double height cell regions in the region 70 is formed of oxide diffusion regions 10 and 12 and the other of oxide diffusion regions 14 and 20a. One cell of the single height cell regions in region 71 is formed of oxide diffusion regions 20 and 22. One cell of the single height cell regions in region 71 is formed of oxide diffusion regions 24 and 26. One cell of the single height cell regions in region 71 is formed of oxide diffusion regions 28 and 29.

In some embodiments, functional block 40 includes a region 70 and an assembled abutting region 5a. Functional block 42 includes a region 71 and an assembled abutting region 5b. Region 70 has oxide diffusion regions 10, 12, 14, and 20a. In some embodiments, assembled abutting region 5a is adjacent to region 71. Region 71 has oxide diffusion regions 20, 22, 24, 26, 29, and 29. Assembled abutting region 5b has dummy oxide diffusion regions 60, 62, 64, 66, 68, and 69.

In some embodiments, oxide diffusion region 10 contacts dummy oxide diffusion region 50. Dummy oxide diffusion region 50 contacts oxide diffusion region 20 in region 71. Oxide diffusion region 20 contacts dummy oxide diffusion region 60. In some embodiments, dummy oxide diffusion region 60 in assembled abutting region 5b is narrower than oxide diffusion region 12 in the region 70.

In some embodiments, an end of dummy oxide diffusion region 50 is aligned with a boundary of functional block 40 from a top view. An end of oxide diffusion region 10 is aligned with a left edge of the boundary of functional block 40 from a top view. In some embodiments, an end of dummy oxide diffusion region 60 is aligned with a boundary of functional block 42 from a top view. An end of oxide diffusion region 20 is aligned with a left edge of the boundary of functional block 42 from a top view.

In some embodiments, oxide diffusion regions 10 and 20a are configured for NMOS technology (the work function is a N-work-function) and oxide diffusion regions 12 and 14 are configured for PMOS technology (the work function is a P-work-function). In some embodiments, oxide diffusion regions 20 and 29 are configured for NMOS technology (the work function is a N-work-function) and oxide diffusion regions 22, 24, 26, and 28 are configured for PMOS technology (the work function is a P-work-function).

FIG. 3B is a top view of a semiconductor device 3b in accordance with some embodiments of the present disclosure. The semiconductor device 3b includes a functional block 40 and a functional block 42. In some embodiments, functional block 40 includes a region 70 which includes two double height cell regions and functional block 42 includes a region 71 which includes three single height cell regions.

In some embodiments, oxide diffusion regions 10 and 20a are configured for NMOS technology (the work function is a N-work-function) and oxide diffusion regions 12 and 14 are configured for PMOS technology (the work function is a P-work-function). In some embodiments, oxide diffusion regions 20 and 29 are configured for NMOS technology (the work function is a N-work-function) and oxide diffusion regions 22, 24, 26, and 28 are configured for PMOS technology (the work function is a P-work-function).

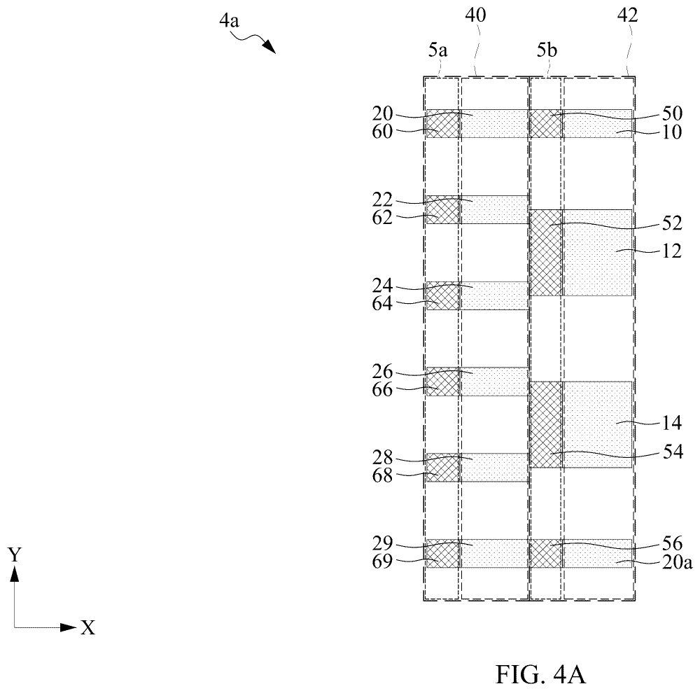

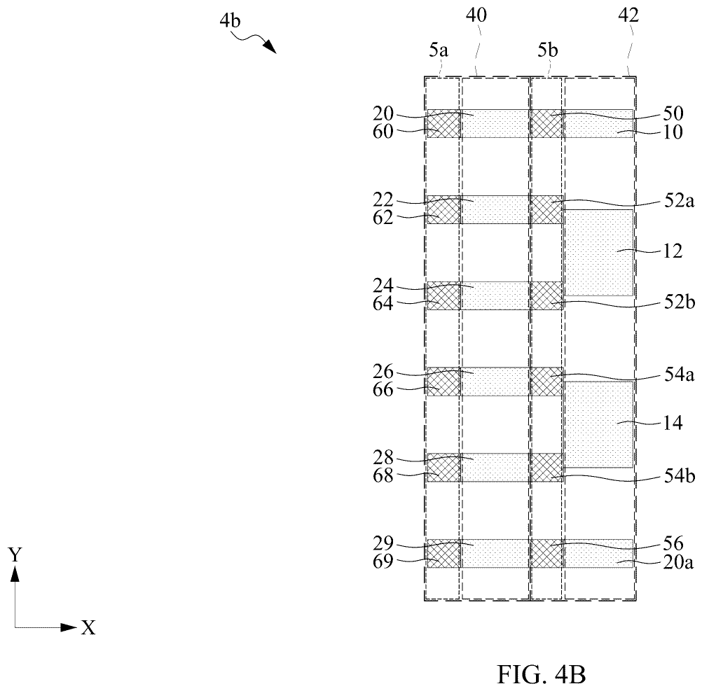

FIG. 4A is a top view of a semiconductor device 4a in accordance with some embodiments of the present disclosure. The semiconductor device 4a includes a functional block 40 and a functional block 42. In some embodiments, functional block 40 includes a region 70 which includes three single height cell regions and functional block 42 includes a region 71 which includes two double height cell regions.

In some embodiments, oxide diffusion regions 10 and 14 are configured for NMOS technology (the work function is a N-work-function) and oxide diffusion regions 12 and 20a are configured for PMOS technology (the work function is a P-work-function). In some embodiments, oxide diffusion regions 20, 26, and 28 are configured for NMOS technology (the work function is a N-work-function) and oxide diffusion regions 22, 24, 28, and 29 are configured for PMOS technology (the work function is a P-work-function).

FIG. 4B is a top view of a semiconductor device 4b in accordance with some embodiments of the present disclosure. The semiconductor device 4b includes a functional block 40 and a functional block 42. In some embodiments, functional block 40 includes a region 70 which includes three single height cell regions and functional block 42 includes a region 71 which includes two double height cell regions.

In some embodiments, oxide diffusion regions 10 and 14 are configured for NMOS technology (the work function is a N-work-function) and oxide diffusion regions 12 and 20a are configured for PMOS technology (the work function is a P-work-function). In some embodiments, oxide diffusion regions 20, 26, and 28 are configured for NMOS technology (the work function is a N-work-function) and oxide diffusion regions 22, 24, 28, and 29 are configured for PMOS technology (the work function is a P-work-function).

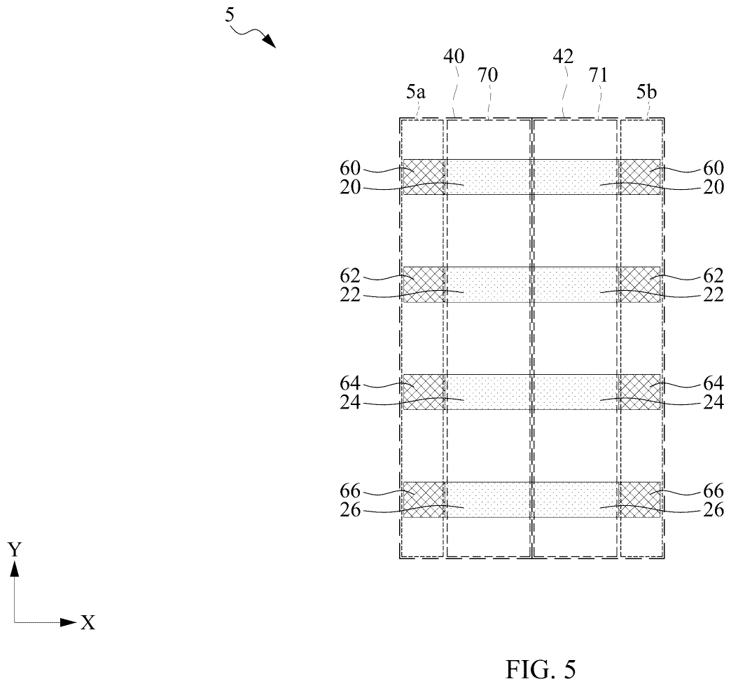

FIG. 5 is a top view of a semiconductor device 5 in accordance with some embodiments of the present disclosure. The semiconductor device 5 includes a functional block 40 and a functional block 42. In some embodiments, functional block 40 includes a region 70 which includes two single height cell regions and functional block 42 includes a region 71 which includes two single height cell regions. Region 70 can be arranged adjacent to the region 71. In some embodiments, assembled abutting regions 5a and 5b can be arranged outside of regions 70 and 71.

In some embodiments, an end of dummy oxide diffusion region 60 in assembled abutting region 5a aligns with a left edge of a boundary of functional block 40 from a top view. Dummy oxide diffusion region 60 in assembled abutting region 5a contacts oxide diffusion region 20 in the region 70. An end of dummy oxide diffusion region 60 aligns with a right edge of the boundary of functional block 42 from a top view. Dummy oxide diffusion region 60 in assembled abutting region 5b contacts oxide diffusion region 20 in region 71. Oxide diffusion region 20 in the region 70 contacts oxide diffusion region 20 in region 71.

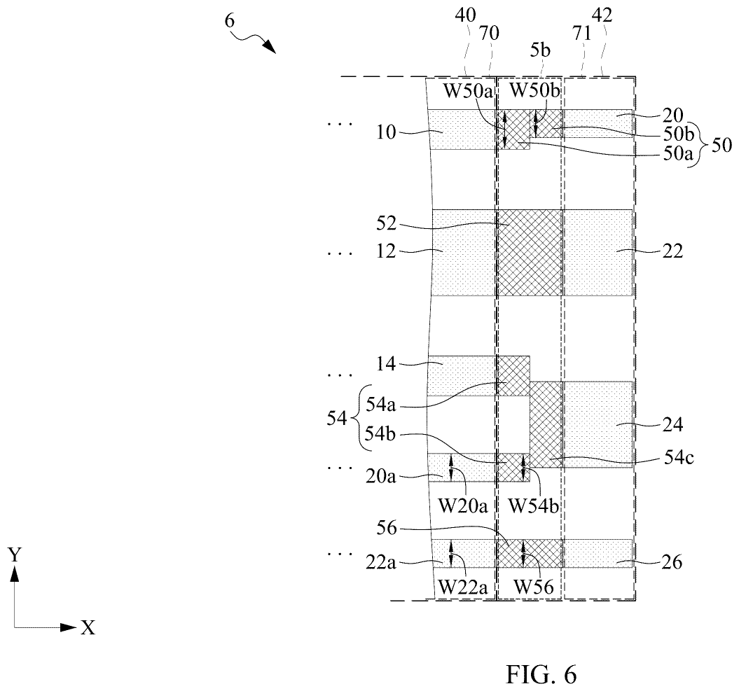

FIG. 6 is a top view of a semiconductor device 6 in accordance with some embodiments of the present disclosure. The semiconductor device 6 includes a functional block 40 and a functional block 42. In some embodiments, functional block 40 includes a region 70 and an assembled abutting region 5a and functional block 42 includes a region 71 and an assembled abutting region 5b.

In some embodiments, an end of dummy oxide diffusion region 50a in assembled abutting region 5b aligns with a left edge of assembled abutting region 5b from a top view. An end of dummy oxide diffusion region 50b in assembled abutting region 5b aligns with a right edge of assembled abutting region 5b from a top view. A width W50a of the dummy oxide diffusion region 50a is greater than a width W50b of the dummy oxide diffusion region 50b. The ends of dummy oxide diffusion regions 54a and 54b in assembled abutting region 5b align with a left edge of assembled abutting region 5b from a top view. Dummy oxide diffusion region 50 further comprises a first portion 50a contacting oxide diffusion region 10 and a second portion 50b contacting oxide diffusion region 20. First portion 50a has a different width from second portion 50b.

In some embodiments, region 70 has oxide diffusion regions 20a and 22a. In some embodiments, oxide diffusion region 20a is contact with dummy oxide diffusion region 54b, and oxide diffusion region 22a is contact with dummy oxide diffusion region 56. In some embodiments, an end of oxide diffusion region 20a (e.g., the end in the right hand) is aligned with a boundary of functional block 40 from a top view. In some embodiments, an end of oxide diffusion region 22a (e.g., the end in the right hand) is aligned with a boundary of functional block 40 from a top view. A width W20a of the oxide diffusion region 20a is substantially equal to a width W54b of the dummy oxide diffusion region 54b. A width W22a of the oxide diffusion region 22a is substantially equal to a width W56 of the dummy oxide diffusion region 56.

First portion 50a aligns with oxide diffusion region 10 and second portion 50b with oxide diffusion region 20 from a top view. First portion 50a and second portion 50b together forms a stepped profile within assembled abutting region 5b from a top view. The stepped profile is disposed at an interface between the first portion 50a and the second portion 50b. The shapes of the stepped profile formed by different dummy oxide diffusion regions may improve the design for area arrangements.

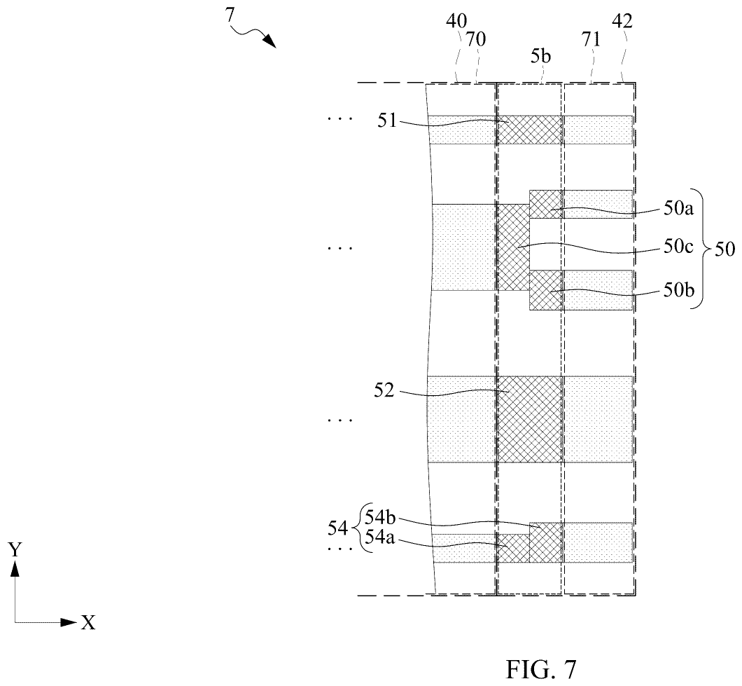

FIG. 7 is a top view of a semiconductor device 7 in accordance with some embodiments of the present disclosure. Semiconductor device 7 includes a functional block 40 and a functional block 42. In some embodiments, functional block 40 includes a region 70 and an assembled abutting region 5a and functional block 42 includes a region 71 and an assembled abutting region 5b.

In some embodiments, the ends of dummy oxide diffusion regions 50a and 50b in assembled abutting region 5b align with a right edge of assembled abutting region 5b from a top view. An end of dummy oxide diffusion region 50c in assembled abutting region 5b aligns with a left edge of assembled abutting region 5b from a top view. An end of dummy oxide diffusion region 54b in assembled abutting region 5b aligns with a right edge of assembled abutting region 5b from a top view. An end of dummy oxide diffusion region 54a in assembled abutting region 5b aligns with a left edge of assembled abutting region 5b from a top view.

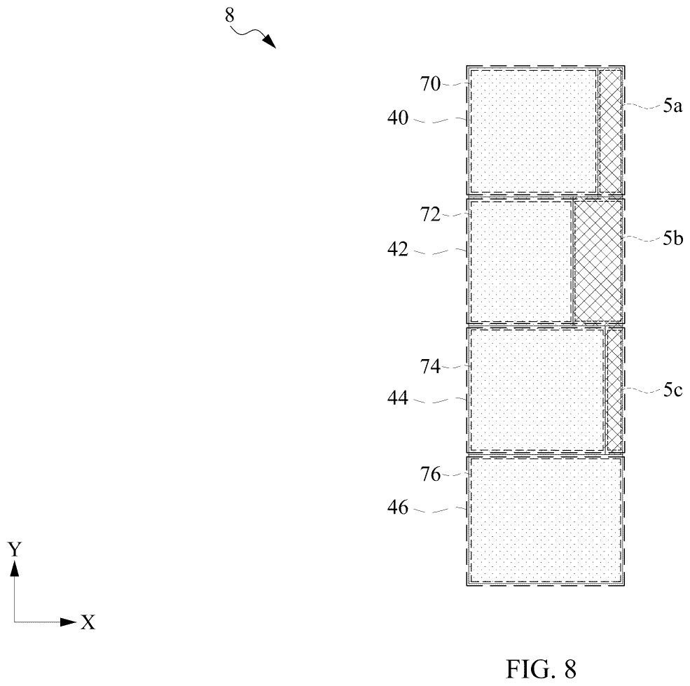

FIG. 8 is a top view of a semiconductor device 8 in accordance with some embodiments of the present disclosure. The semiconductor device 8 includes functional blocks 40, 42, 44, and 46. In some embodiments, functional block 40 includes a region 70 and an assembled abutting region 5a, and functional block 42 includes a region 71 and an assembled abutting region 5b. In some embodiments, functional block 44 includes a region 74 and an assembled abutting region 5c, and functional block 46 includes a region 76. In some embodiments, a left edge of the boundary of functional block 40 aligns with a left edge of the boundary of functional block 42 from a top view. In some embodiments, a left edge of the boundary of the functional block 44 aligns with a left edge of the boundary of functional block 46 from a top view. In some embodiments, a right edge of the boundary of functional block 40 aligns with a right edge of the boundary of functional block 42 from a top view. In some embodiments, a bottom edge of the boundary of functional block 40 aligns with a top edge of the boundary of functional block 42 from a top view.

In some embodiments, the alignment of the boundary of each of the functional blocks 40, 42, 44, and 46 may improve the area matching (or alignment) of a plurality of functional blocks when designing the device. In some embodiments, the area of the region 72 is smaller than the area of the region 70 and the area of the assembled abutting region 5b is greater than the area of the assembled abutting region 5a. The assembled abutting region 5b may compensate for the lack of the area of the region 70. That is, a sum of the area of region 70 and the area of assembled abutting region 5a is substantially equal to a sum of the area of region 72 and the area of the assembled abutting region 5b.

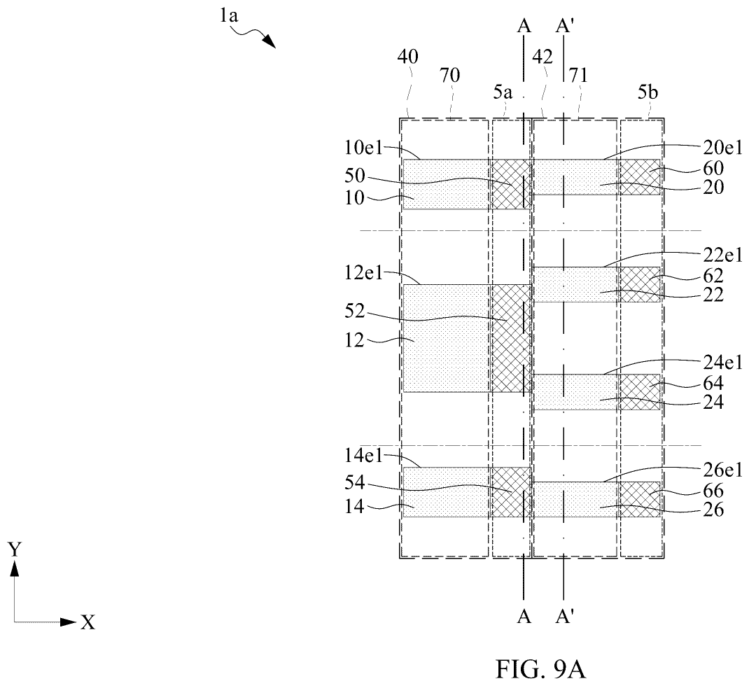

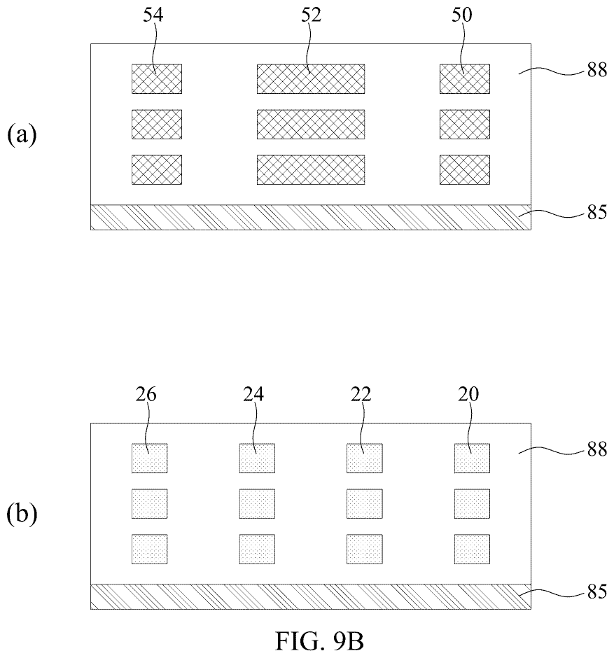

FIG. 9A is a top view of the semiconductor device 1a in accordance with some embodiments of the present disclosure. FIG. 9A shows two dotted lines A-A and A′-A′ across the semiconductor device 1a.

FIG. 9B shows two cross-sections (a) and (b) of the semiconductor device 1a respectively along lines A-A and A′-A′ of FIG. 9A, in accordance with some embodiments of the present disclosure. The semiconductor device 1a includes a semiconductor substrate 85 and a dielectric layer 88 on the semiconductor substrate 85. The semiconductor device 1a is formed in the dielectric layer 88. Cross-section (a) shows that the dielectric layer 88 includes three layers of dummy oxide diffusion region 50, three layers of dummy oxide diffusion region 52, and three layers of dummy oxide diffusion region 54 formed therein. While three layers of dummy oxide diffusion regions 50, 52, and 54 are shown, it is possible to implement dummy oxide diffusion regions using a different number of layers, such as a single layer, two layers, or more than three layers.

Cross-section (b) shows that the dielectric layer 88 includes three layers of oxide diffusion region 20, three layers of oxide diffusion region 22, three layers of oxide diffusion region 24, and three layers of dummy oxide diffusion region 26 formed therein. While three layers of oxide diffusion regions 20, 22, 24, and 26 are shown, it is possible to implement oxide diffusion regions using a different number of layers, such as a single layer, two layers, or more than three layers.

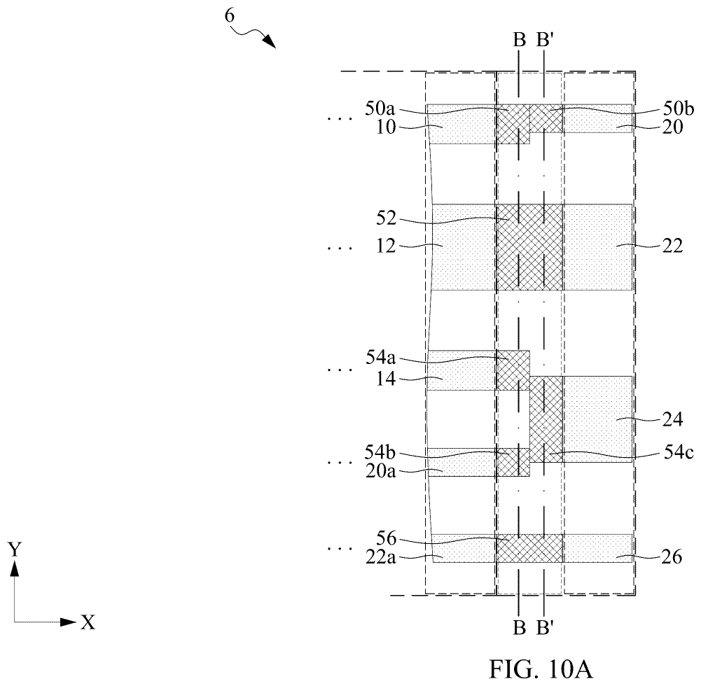

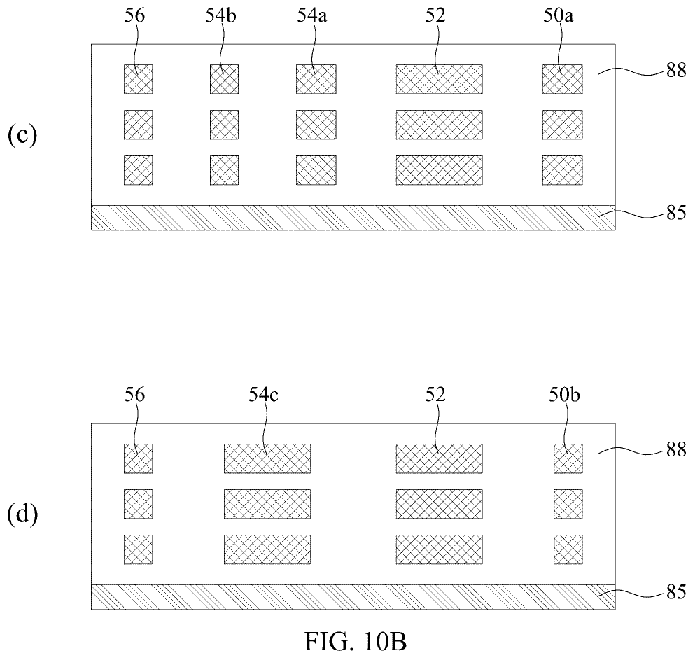

FIG. 10A is a top view of the semiconductor device 6 in accordance with some embodiments of the present disclosure. FIG. 10A shows two dotted lines B-B and B′-B′ across the semiconductor device 6.

FIG. 10B shows two cross-sections (c) and (d) of the semiconductor device 6 along lines B-B and B′-B′ of FIG. 10A in accordance with some embodiments of the present disclosure. The semiconductor device 6 includes a semiconductor substrate 85 and a dielectric layer 88 on the semiconductor substrate 85. The semiconductor device 6 is formed in the dielectric layer 88. Cross-section (c) shows that the dielectric layer 88 includes three layers of dummy oxide diffusion region 50a, three layers of dummy oxide diffusion region 52, three layers of dummy oxide diffusion region 54a, three layers of dummy oxide diffusion region 54b, and three layers of dummy oxide diffusion region 56 formed therein. While three layers of dummy oxide diffusion regions 50a, 52, 54a, 54b, and 56 are shown, it is possible to implement dummy oxide diffusion regions using a different number of layers, such as a single layer, two layers, or more than three layers.

Cross-section (d) shows that the dielectric layer 88 includes three layers of dummy oxide diffusion region 50b, three layers of dummy oxide diffusion region 52, three layers of dummy oxide diffusion region 54c, and three layers of dummy oxide diffusion region 56 formed therein. While three layers of dummy oxide diffusion regions 50b, 52, 54c, and 56 are shown, it is possible to implement dummy oxide diffusion regions using a different number of layers, such as a single layer, two layers, or more than three layers.

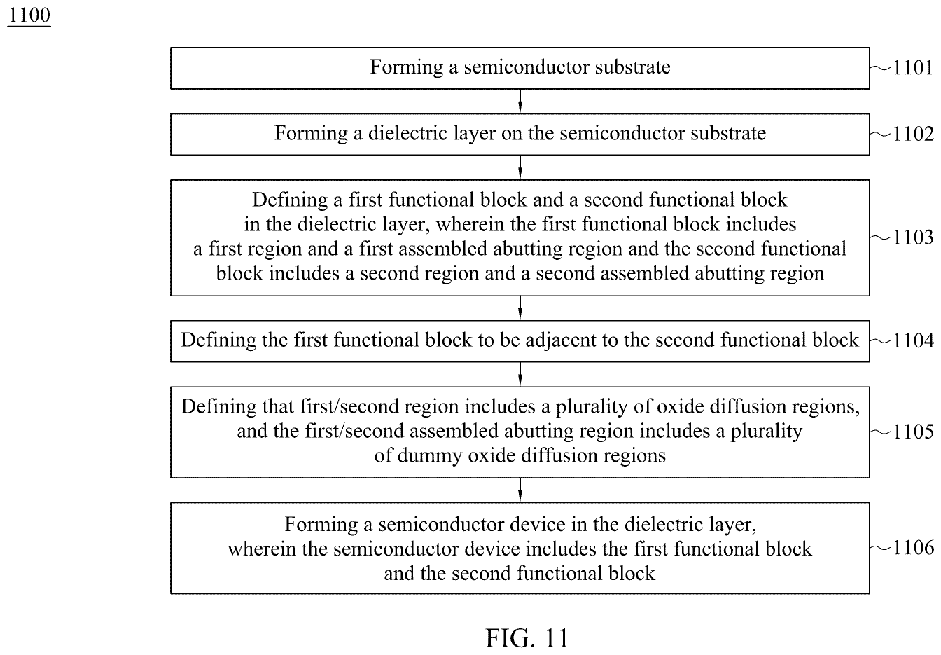

FIG. 11 is a flowchart of an embodiment of a method 1100 of manufacturing a semiconductor device 1a in accordance with some embodiments of the present disclosure. In some embodiments, the method may include various operations for manufacturing the semiconductor device 1a. The method 1100 includes forming a semiconductor substrate 85 (operation 1101). The method 1100 includes forming a dielectric layer 88 on the semiconductor substrate 85 (operation 1102). The method 1100 includes defining a first functional block 40 and a second functional block 42 in the dielectric layer 88, wherein the first functional block 40 includes a first region 70 and a first assembled abutting region 5a and the second functional block 42 includes a second region 71 and a second assembled abutting region 5b (operation 1103).

The method 1100 further includes defining the first functional block 40 to be adjacent to the second functional block 42 (operation 1104). The method 1100 further includes defining that the first/second region 70/71 includes a plurality of oxide diffusion regions, and the first/second assembled abutting region 5a/5b includes a plurality of dummy oxide diffusion regions, wherein the number of the dummy oxide diffusion regions in the assembled abutting region 5a/5b may be equal to or different from the number of the oxide diffusion regions in region 70/71 (operation 1105) In some embodiments, wherein a width of one of the dummy oxide diffusion regions in the assembled abutting region 5a/5b may be equal to or different from a width of one of the oxide diffusion regions in region 70/71. In some embodiments, wherein a width of one of the dummy oxide diffusion regions in the assembled abutting region 5a/5b may be equal to or different from a width of one of the oxide diffusion regions in region 70/71. The method 1100 includes forming a semiconductor device 1a in the dielectric layer 88, wherein the semiconductor device 1a includes the first functional block 40 and the second functional block 42 (operation 1106). The present disclosure reduces the area of the semiconductor device 1a by aligning one end of assembled abutting region 5a with the boundary of functional block 40 from a top view and aligning one end of dummy oxide diffusion region 50 with the boundary of functional block 40 from a top view. The method or semiconductor device in accordance with some embodiments of the present disclosure includes, but not limited to, the mentioned processes.

According to some embodiments, a semiconductor device comprises a first functional block. The first functional block includes a first region having a first oxide diffusion region and a second oxide diffusion region. A first assembled abutting region is adjacent to the first region and comprises a first dummy oxide diffusion region and a second dummy oxide diffusion region. The first oxide diffusion region is contact with the first dummy oxide diffusion region. The second oxide diffusion region is contact with the second dummy oxide diffusion region. An end of the first dummy oxide diffusion region is aligned with a boundary of the first functional block from the top view. An end of the second dummy oxide diffusion region is aligned with the boundary of the first functional block from the top view.

According to other embodiments, a semiconductor device comprises a first functional block. The first functional block comprises a first region having a first oxide diffusion region and a second oxide diffusion region. The first assembled abutting region is adjacent to the first region and has a first dummy oxide diffusion region and a second dummy oxide diffusion region. The second dummy oxide diffusion region comprises an upper dummy oxide diffusion region and a lower dummy oxide diffusion region. The first oxide diffusion region is contact with and is aligned with the first dummy oxide diffusion region. The second oxide diffusion region is contact with the upper dummy oxide diffusion region and the lower dummy oxide diffusion region. An end of the first oxide diffusion region is aligned with a boundary of the first functional block and an end of the second oxide diffusion region is aligned with the boundary of the first functional block from the top view.

According to some embodiments, a method for manufacturing a semiconductor device comprises forming a semiconductor substrate; forming a dielectric layer on the semiconductor substrate; forming a semiconductor device in the dielectric layer; wherein the semiconductor device comprises: a first functional block comprising: a first region having a first oxide diffusion region and a second oxide diffusion region; a first assembled abutting region adjacent to the first region and comprising a first dummy oxide diffusion region and a second dummy oxide diffusion region, wherein the first oxide diffusion region is contact with the first dummy oxide diffusion region; the second oxide diffusion region is contact with the second dummy oxide diffusion region; an end of the first dummy oxide diffusion region is aligned with a boundary of the first functional block from the top view; and an end of the second dummy oxide diffusion region is aligned with the boundary of the first functional block from the top view.

The methods and features of the present disclosure have been sufficiently described in the examples and descriptions provided. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor device comprising:
a first functional block comprising:
a first region having a first oxide diffusion region and a second oxide diffusion region;
a first assembled abutting region adjacent to the first region and comprising a first dummy oxide diffusion region and a second dummy oxide diffusion region, wherein
the first oxide diffusion region is contact with the first dummy oxide diffusion region;
the second oxide diffusion region is contact with the second dummy oxide diffusion region;
an end of the first dummy oxide diffusion region is aligned with a boundary of the first functional block from the top view; and
an end of the second dummy oxide diffusion region is aligned with the boundary of the first functional block from the top view.

2. The semiconductor device of claim 1, further comprising:
a second functional block comprising:
a second region having a third oxide diffusion region in contact with the first dummy oxide diffusion region and a fourth oxide diffusion region in contact with the second dummy oxide diffusion region from the top view;
a second assembled abutting region adjacent to the second region and comprising a third dummy oxide diffusion region in contact with the third oxide diffusion region and a fourth dummy oxide diffusion region in contact with the fourth oxide diffusion region, wherein
an end of the third dummy oxide diffusion region is aligned with a boundary of the second functional block and an end of the fourth dummy oxide diffusion region is aligned with the boundary of the second functional block from the top view.

3. The semiconductor device of claim 2, wherein a width of the third dummy oxide diffusion region is smaller than a width of the first oxide diffusion region and a width of the fourth dummy oxide diffusion region is smaller than a width of the second oxide diffusion region.

4. The semiconductor device of claim 2, wherein a width of the first dummy oxide diffusion region is different from a width of the third dummy oxide diffusion region from the top view, and wherein a width of the second dummy oxide diffusion region is different from a width of the fourth oxide diffusion region.

5. The semiconductor device of claim 2, wherein a width of the third oxide diffusion region is the same as a width of third dummy oxide diffusion region, and a width of fourth oxide diffusion region is the same as a width of the fourth dummy oxide diffusion region.

6. The semiconductor device of claim 2, wherein the second oxide diffusion region has a first edge extending along a first direction orthogonal to the end of the first dummy oxide diffusion region, and wherein the fourth oxide diffusion region has a second edge adjacent to the first edge and extending along the first direction, wherein the first edge is not aligned with the second edge from the top view.

7. The semiconductor device of claim 2, wherein the second dummy oxide diffusion region comprises an upper dummy oxide diffusion region and a lower dummy oxide diffusion region separated from the upper dummy oxide diffusion region, wherein a lower portion of the upper dummy oxide diffusion region is in contact with the second oxide diffusion region and an upper portion of the lower dummy oxide diffusion region is in contact with the second oxide diffusion region from the top view.

8. The semiconductor device of claim 7, further comprising a fifth oxide diffusion region disposed in the second region, wherein the upper dummy oxide diffusion region is aligned with the fourth oxide diffusion region and the lower dummy oxide diffusion region is aligned with the fifth oxide diffusion region from the top view.

9. The semiconductor device of claim 8, wherein the first dummy oxide diffusion region further comprises a first portion in contact with the first oxide diffusion region and a second portion in contact with the third oxide diffusion region, wherein a width of the first portion is different than a width of the second portion.

10. The semiconductor device of claim 9, wherein the first portion is aligned with the first oxide diffusion region and the second portion is aligned with the third oxide diffusion region from the top view, and wherein the first portion and the second portion collectively form a stepped profile in the conjunction therebetween within the second assembled abutting region from the top view.

11. A semiconductor device comprising:
a first functional block comprising:
a first region having a first oxide diffusion region and a second oxide diffusion region;
a first assembled abutting region adjacent to the first region and having a first dummy oxide diffusion region and a second dummy oxide diffusion region, wherein
the second dummy oxide diffusion region comprises an upper dummy oxide diffusion region and a lower dummy oxide diffusion region;
the first oxide diffusion region is contact with and is aligned with the first dummy oxide diffusion region;
the second oxide diffusion region is contact with the upper dummy oxide diffusion region and the lower dummy oxide diffusion region; and
wherein an end of the first oxide diffusion region is aligned with a boundary of the first functional block and an end of the second oxide diffusion region is aligned with the boundary of the first functional block from the top view.

12. The semiconductor device of claim 11, comprising:
a second functional block comprising:
a second region having a third oxide diffusion region in contact with the first dummy oxide diffusion region and a fourth oxide diffusion region in contact with and aligned with the upper dummy oxide diffusion region from the top view;
a second assembled abutting region adjacent to the second region and comprising a third dummy oxide diffusion region in contact with the third oxide diffusion region and a fourth dummy oxide diffusion region in contact with the fourth oxide diffusion region, wherein
an end of the third dummy oxide diffusion region is aligned with a boundary of the second functional block and an end of the fourth dummy oxide diffusion region is aligned with the boundary of the second functional block from the top view; and
a width of the third dummy oxide diffusion region is smaller than a width of the first oxide diffusion region and a width of the third dummy oxide diffusion region is the same as a width of the third oxide diffusion region.

13. The semiconductor device of claim 12, wherein a width of the upper dummy oxide diffusion region is the same from a width of the fourth oxide diffusion region.

14. The semiconductor device of claim 12, wherein and a width of fourth oxide diffusion region is the same as a width of the fourth dummy oxide diffusion region.

15. The semiconductor device of claim 12, wherein the second oxide diffusion region has a first edge extending along a first direction orthogonal to the end of the first dummy oxide diffusion region, and wherein the fourth oxide diffusion region has a second edge adjacent to the first edge and extending along the first direction, wherein the first edge is not aligned with the second edge from the top view.

16. The semiconductor device of claim 11, wherein a lower portion of the upper dummy oxide diffusion region is in contact with the second oxide diffusion region and an upper portion of the lower dummy oxide diffusion region is in contact with the second oxide diffusion region from the top view.

17. The semiconductor device of claim 11, wherein the first dummy oxide diffusion region further comprises a first portion in contact with the first oxide diffusion region and a second portion in contact with the third oxide diffusion region, wherein a size of the first portion is different than a size of the second portion.

18. A method for manufacturing a semiconductor device comprising:
forming a semiconductor substrate;
forming a dielectric layer on the semiconductor substrate;
forming a semiconductor device in the dielectric layer;
wherein the semiconductor device comprises:
a first functional block comprising:
a first region having a first oxide diffusion region and a second oxide diffusion region;
a first assembled abutting region adjacent to the first region and comprising a first dummy oxide diffusion region and a second dummy oxide diffusion region, wherein
the first oxide diffusion region is contact with the first dummy oxide diffusion region;
the second oxide diffusion region is contact with the second dummy oxide diffusion region;
an end of the first dummy oxide diffusion region is aligned with a boundary of the first functional block from the top view; and
an end of the second dummy oxide diffusion region is aligned with the boundary of the first functional block from the top view.

19. The method of claim 18, wherein the semiconductor device further comprises:
a second functional block comprising:
a second region having a third oxide diffusion region in contact with the first dummy oxide diffusion region and a fourth oxide diffusion region in contact with the second dummy oxide diffusion region from the top view;
a second assembled abutting region adjacent to the second region and comprising a third dummy oxide diffusion region in contact with the third oxide diffusion region and a fourth dummy oxide diffusion region in contact with the fourth oxide diffusion region, wherein
an end of the third dummy oxide diffusion region is aligned with a boundary of the second functional block and an end of the fourth dummy oxide diffusion region is aligned with the boundary of the second functional block from the top view.

20. The method of claim 19, wherein a width of the third dummy oxide diffusion region is smaller than a width of the first oxide diffusion region and a width of the fourth dummy oxide diffusion region is smaller than a width of the second oxide diffusion region.
